(19) United States
(12) Patent Application Publication
(10) Pub. No.: US 2022/0246814 A1
(43) Pub. Date: Aug. 4, 2022

(54) MICRO LIGHT-EMITTING DEVICE, METHOD FOR MAKING THE SAME AND DISPLAY SCREEN

(71) Applicant: XIAMEN SAN'AN OPTOELECTRONICS CO., LTD., Xiamen (CN)

(72) Inventors: Yenchin WANG, Xiamen (CN); Huanshao KUO, Tianjin (CN); Yu-Ren PENG, Tianjin (CN); Shuiqing LI, Xiamen (CN); Shaohua HUANG, Xiamen (CN)

(21) Appl. No.: 17/588,940

(22) Filed: Jan. 31, 2022

(30) Foreign Application Priority Data
Feb. 3, 2021 (CN) 202110149040.2

(51) Int. Cl. H01L 33/62; H01L 33/10; H01L 33/00

(52) U.S. Cl. CPC H01L 33/62; H01L 33/0095; H01L 33/10

(57) ABSTRACT

A micro light-emitting device includes an epitaxial unit and a current-spreading layer. The epitaxial unit has a top portion that includes an ohmic contact region and a non-ohmic contact region. The top portion has a periphery area which forms at least a part of the non-ohmic contact region. The periphery area has a reduced conductivity compared with the remainder of the top portion. The current-spreading layer is disposed on the ohmic contact region. A method for making the micro light-emitting device, and a display screen including the same are also disclosed.

### CROSS-REFERENCE TO RELATED APPLICATION

This application claims priority of Chinese Invention Patent Application No. 202110149040.2, filed on Feb. 3, 2021.

### FIELD

The disclosure relates to a micro light-emitting device, and a method for making the same. The disclosure also relates to a display screen including the micro light-emitting device.

### BACKGROUND

A micro light-emitting diode (micro LED) has advantages such as small size, light weight, high brightness, long service life, low power consumption, short response time and good controllability, and thus has been used in a new generation of a display device. Furthermore, the micro LED may have a color gamut wider than 120% as compared with a liquid-crystal display (LCD), and have a pixel density (i.e., the number of pixel per inch) as much as 1500.

A micro LED with a size smaller than 50 μm may have defects on a side wall thereof, thereby resulting in current leakage. Meanwhile, dangling bonds at the defective side wall may cause non-radiative re-combinations, and thus influences luminous efficiency of the micro LED.

When the size of the micro LED is further reduced, non-radiative re-combinations caused by the defective side wall of the micro LED would become more severe.

In order to solve the aforesaid problems, the following two approaches are provided.

1. Altering a design of a metal electrode on a current-spreading layer to reach different current spreading effect.

In this approach, due to an annealing process conducted on the metal electrode or lower reflectivity of the metal electrode, light might be absorbed by the metal electrode, and thus a luminous efficiency might be decreased.

2. Using a transparent electrode on the current-spreading layer to change current path.

In this approach, although the current might be prevented from flowing through a periphery of a mesa of the micro LED to reduce non-radiative re-combinations, the current spreading efficiency achieved by the transparent electrode might not meet industrial requirements.

### SUMMARY

Therefore, an object of the disclosure is to provide a micro light-emitting device, a method for making the same, and a display screen including the micro light-emitting device, which can alleviate or eliminate at least one of the drawbacks of the prior art.

According to a first aspect of the disclosure, a micro light-emitting device includes an epitaxial unit and a current-spreading layer.

The epitaxial unit has a top portion that includes an ohmic contact region and a non-ohmic contact region. The top portion has a periphery area which forms at least a part of the non-ohmic contact region. The periphery area has a reduced conductivity compared with the remainder of the top portion.

The current-spreading layer is disposed on the ohmic contact region.

According to a second aspect of the disclosure, a method for making a micro light-emitting device includes the steps of:

forming an epitaxial unit that includes a first type semiconductor layer, an active layer and a second type semiconductor layer, the epitaxial unit having a top portion which has a periphery area;

subjecting the periphery area of the epitaxial unit to surface treatment so that the periphery area has a reduced conductivity compared with a remainder of the top portion so as to form a non-ohmic contact region; and

forming a current-spreading layer on the epitaxial unit, at least a part of the top portion of the epitaxial unit in contact with the current-spreading layer forming an ohmic contact region.

According to a third aspect of the disclosure, a display screen includes the aforesaid micro light-emitting device.

### BRIEF DESCRIPTION OF THE DRAWINGS

Other features and advantages of the disclosure will become apparent in the following detailed description of the embodiments with reference to the accompanying drawings, of which:

FIG. 1 is a schematic view illustrating a first embodiment of a micro light-emitting device according to the disclosure;

FIG. 2 is a schematic view illustrating a method for making the first embodiment of the micro light-emitting device, in which a silicon dioxide layer is formed on an epitaxial unit;

FIG. 3 is a schematic view illustrating a photoresist layer-forming step of the method for making the first embodiment of the micro light-emitting device;

FIG. 4 is a schematic view illustrating a second embodiment of the micro light-emitting device according to the disclosure;

FIG. 5 is a schematic view illustrating a third embodiment of the micro light-emitting device according to the disclosure;

FIG. 6 is a schematic view illustrating a fourth embodiment of the micro light-emitting device according to the disclosure;

FIG. 7 is a schematic view illustrating a fifth embodiment of the micro light-emitting device according to the disclosure;

FIG. 8 is a schematic view illustrating a sixth embodiment of the micro light-emitting device according to the disclosure;

FIG. 9 is a schematic view illustrating a seventh embodiment of the micro light-emitting device according to the disclosure;

FIG. 10 is a schematic view illustrating an eighth embodiment of the micro light-emitting device according to the disclosure; and

FIG. 11 illustrates a display screen that includes the aforesaid micro light-emitting device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

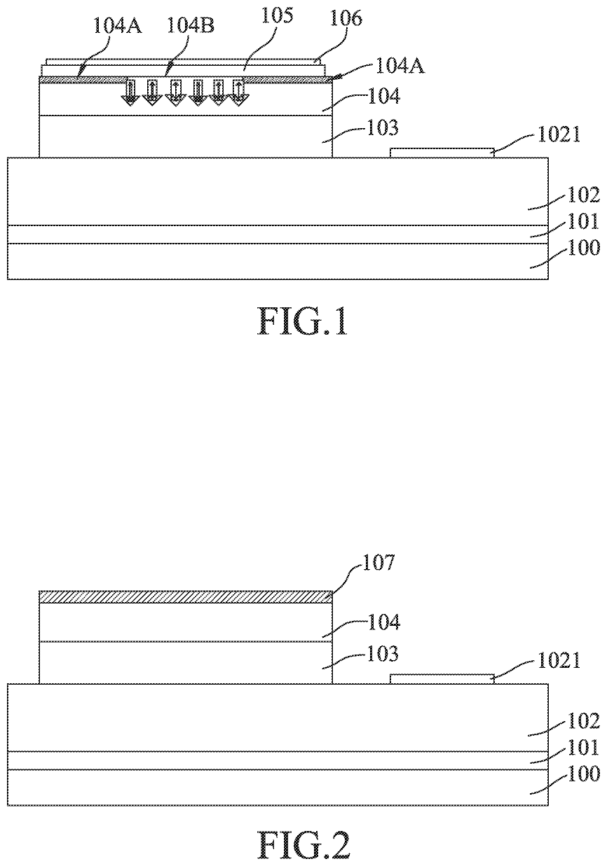

Referring to FIG. 1, a first embodiment of a micro light-emitting device 201 according to the present disclosure includes an epitaxial unit, a current-spreading layer 105, and a first electrode 1021.

The epitaxial unit includes a substrate 100, a buffer layer 101 on the substrate 100, a first type semiconductor layer 102 on the buffer layer 101, an active layer 103 on the first type semiconductor layer 102, and a second type semiconductor layer 104 on the active layer 103. The aforesaid layers are laminated in a laminating direction. The epitaxial unit is shaped to have a mesa structure that includes a first mesa portion and a second mesa portion. The first mesa portion is a part of the first type semiconductor layer 102. The first electrode 1021 is disposed on the first mesa portion, and is electrically connected to the first type semiconductor layer 102. The second mesa portion is a part of the second type semiconductor layer 104.

Each of the layers of the epitaxial unit may be a single layer or a multi-layered structure. For example, each of the first type semiconductor 102 and the second type semiconductor layer 104 may be a laminating structure with two or more sub-layers. Materials and methods for forming these layers may be known to a person skilled in the art, and thus, detailed description thereof is omitted herein for brevity.

The epitaxial unit has a top portion that includes an ohmic contact region 104B and a non-ohmic contact region. The top portion has a periphery area 104A which forms at least a part of the non-ohmic contact region. The periphery area 104A has a reduced conductivity compared with the remainder of the top portion. The current-spreading layer 105 may be disposed on the ohmic contact region 104B.

Referring to FIG. 1, in the first embodiment, the top portion is a part of the second type semiconductor layer 104, and the periphery area 104A is the non-ohmic contact region of the top portion of the epitaxial unit. The periphery area 104A is formed by ion implantation of a peripheral part of the top portion so that the periphery area 104A is an ion implanting area having a high impedance. By virtue of ion implantation, the periphery area 104A has a reduced conductivity.

In the first embodiment, the current-spreading layer 105 is disposed not only on the ohmic contact region 104B but also on the periphery area 104A. Such configuration may simplify a process for manufacturing the micro light-emitting device 201, and provide structural integrity and improved stability.

Argon ions (Ar) or nitrogen ions (N) may be used in ion implantation, so that the periphery area 104A of the non-ohmic contact region may include argon ions (Ar) or nitrogen ions (N).

In the first embodiment, the periphery area 104A having high impedance and reduced conductivity may not conduct current regardless of a material of a neighboring layer which is in contact with the periphery area 104A. In other words, the periphery area 104A that has the implanted ions may prevent the currents from spreading toward a periphery of the epitaxial unit. In case that the periphery area 104A is in contact with the current-spreading layer 105 or a metal layer (e.g., a metal reflective layer 106), ohmic contact may not be formed, and thus, current conduction may not occur. Thus, non-radiative re-combinations caused by current flowing through a periphery of the mesa structure may be avoided. Therefore, a luminous efficiency of the micro light-emitting device 201 under a low current density may be improved.

Arrows shown in FIG. 1 indicate flow direction of current in the micro light-emitting device 201, and shows that the current only flows in a location corresponding to the ohmic contact region 104B. Therefore, the micro light-emitting device 201 according to the disclosure ensures that the current flows toward desired regions, and a current density is thus increased so as to improve the performance of the micro light-emitting device 201.

As mentioned above, the top portion is a part of the second type semiconductor layer 104. To be specific, in this embodiment, the top portion is an upper portion of the second type semiconductor layer 104, and is the second mesa portion of the mesa structure. Thus, the second mesa portion includes the ohmic contact region 104B and the non-ohmic contact region. The mesa structure is formed by various etching processes. Since the mesa structure and the method for forming the same is known to a person skilled in the art, detail description thereof is omitted herein for brevity.

The ohmic contact region 104B of the second type semiconductor layer 104 is in contact with the current-spreading layer 105. The periphery area 104A of the second type semiconductor layer 104 includes the implanted ions and is in contact with the current-spreading layer 105.

A roughness of the periphery area 104A is greater than a roughness of the ohmic contact region 104B. The periphery area 104A formed by ion implantation has the roughness ranging from 3 nm to 30 nm.

A material for the current-spreading layer 105 includes a transparent conductive material (e.g., indium titanium oxide (ITO), indium zinc oxide (IZO), or zinc oxide (ZnO)).

Referring to FIG. 1, in the first embodiment, the micro light-emitting device 201 further includes a metal reflective layer 106 disposed on the current-spreading layer 105. The metal reflective layer 106 is formed after forming the periphery area 104A by ion implantation and the current-spreading layer 105. Therefore, reflectivity of light from the active layer 103 may be increased so as to increase the luminous efficiency. In addition, the metal reflective layer 106 may cooperate with the ohmic contact region 104B and the non-ohmic contact region to control current spreading, so as to prevent non-radiative re-combinations, thereby increasing current density and improving luminous efficiency.

The metal reflective layer 106 may be made of a metal reflective mirror material, e.g., gold, aluminum, silver, nickel-gold alloy, titanium-gold alloy, platinum, or combinations thereof.

The arrangement of the metal reflective layer 106 allows the micro light-emitting device 201 of this embodiment to be made into a flip-chip structure, so that the micro light-emitting device 201 may have the advantages attributed to the flip-chip structure.

In some embodiments, the micro light-emitting device 201 may not include the metal reflective layer 106, and thus a wire bonding procedure may be utilized in the method for making the micro light-emitting device 201. In other embodiments, the micro light-emitting device 201 may be formed into a vertical LED structure.

In certain embodiments, the second type semiconductor layer 104 may be made of gallium phosphide that produces red light or a P-type gallium nitride that produces blue light. The current-spreading layer 105 may be made of indium titanium oxide (ITO), and may have a sufficient thickness to obtain a good ohmic contact. In this embodiment, the current-spreading layer 105 has a thickness ranging from 10 Å to 3000 Å.

In certain embodiments, the metal reflective layer 106 may have a thickness not less than 300 Å so as to have desired reflectivity.

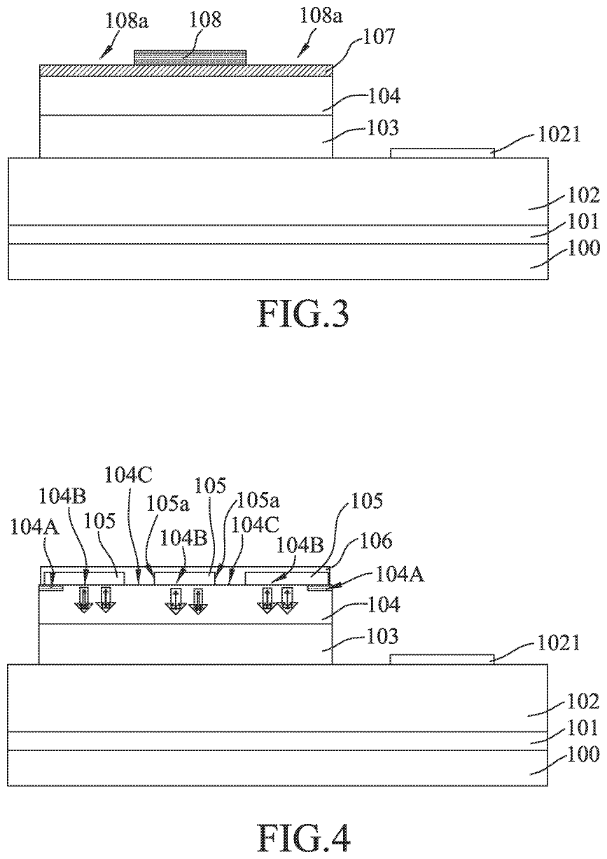

Referring to FIGS. 2 and 3, a method for making the first embodiment of the micro light-emitting device 201 is provided.

The method includes the following steps.

First, the epitaxial unit is provided by forming the buffer layer 101 on the substrate 100, forming the first type semiconductor layer 102 on the buffer layer 101, forming the active layer 103 on the first type semiconductor layer 102, and forming the second type semiconductor layer 104 on the active layer 103.

Afterward, the periphery area 104A of the top portion of the epitaxial unit is subjected to surface treatment, so that the periphery area 104A has a reduced conductivity compared with the remainder of the top portion, and so that the periphery area 104A forms the non-ohmic contact region.

Then, the current-spreading layer 105 is formed on the epitaxial unit. At least a part of the top portion of the epitaxial unit that is in contact with the current-spreading layer 105 forms an ohmic contact region 104B.

In certain embodiments, the step of subjecting the periphery area 104A of the epitaxial unit to surface treatment may include the following sub-steps.

First of all, referring to FIG. 2, a silicon dioxide (SiO₂) layer 107 is formed on the top portion of the epitaxial unit.

Referring to FIG. 3, a photoresist layer 108 is then formed on the silicon dioxide layer 107. The photoresist layer 108 is non-overlapping with the periphery area 104A (see FIG. 1) of the top portion. To be specific, the photoresist layer 108 has openings 108a that is registered with the periphery area 104A of the top portion.

Afterward, ion implantation is conducted using the photoresist layer 108 as a mask, so that the periphery area 104A of the top portion is implanted with ions, and the other area of the top portion that is registered with the photoresist layer 108 is not implanted with ions.

The silicon dioxide layer 107 on the periphery area 104A is exposed from the photoresist layer 108.

A ratio of an area of a surface of the periphery area 104A to an area of a surface of the top portion of the epitaxial unit ranges from 30% to 80%. In this embodiment, such ratio is 35%.

It is noted that, the silicon dioxide layer 107 may have a thickness ranging from 100 Å to 2000 Å. The silicon dioxide layer 107 assists diffusion of the implanted ions. The sub-step of forming the photoresist layer 108 may be conducted using a photolithography process. A thickness of the photoresist layer 108 may be twice an implanted depth of the periphery area 104A. The implanted depth may be the same as a thickness of the top portion. In certain embodiments, the thickness of the photoresist layer 108 may be the same as a thickness of the second type semiconductor layer 104.

An incident angle of an ion beam for performing ion implantation may range from 0 to 7 degrees.

The method further includes removing the silicon dioxide layer 107 and the photoresist layer 108, and then forming the metal reflective layer 106 so as to obtain the micro light-emitting device 201 shown in FIG. 1.

FIG. 4 shows a second embodiment of the micro light-emitting device 201 according to the disclosure.

The second embodiment is similar to the first embodiment, except that, in the second embodiment, the current-spreading layer 105 is patterned to be formed with a plurality of through holes 105a. It should be noted that, in the second embodiment, the current-spreading layer 105 is still a continuous layer, and the through holes 105a are distributed in the current-spreading layer 105.

The through holes 105a may have a variety of cross-sectional shapes taken along a surface of the current-spreading layer 105 that is perpendicular to the laminating direction. The cross-sectional shape may be, e.g., round shape, polygon shape, etc.

Referring to FIG. 4, in this embodiment, the periphery area 104A and the current-spreading layer 105 are both directly covered by the metal reflective layer 106. That is to say, the metal reflective layer 106 is disposed directly on the thus patterned current-spreading layer 105.

In this embodiment, since the current-spreading layer 105 is formed with the through holes 105a, the metal reflective layer 106 fills the through holes 105a, and is in direct contact with the second type semiconductor layer 104. The exposed part 104C of the top portion of the epitaxial unit (i.e., the part of the second type semiconductor layer 104 that is exposed from the through holes 105a, is in contact with the metal reflective layer 106, and not in contact with the current-spreading layer 105) belongs to a part of the non-ohmic contact region.

In other words, in this embodiment, the non-ohmic contact region includes the periphery area 104A and the exposed part 104C of the top portion.

In the second embodiment, the conductivity of the periphery area 104A formed by ion implantation is lower than that of the exposed part 104C of the top portion. In this embodiment, apart from the periphery area 104A, the exposed part 104C of the top portion is also capable of controlling the flow of current.

As shown in FIG. 4, the flow direction of current in the micro light-emitting device 201 is also indicated by arrows. The current is conducted in the ohmic contact region 104B. Therefore, the structure of the second embodiment may ensure that the current flows at desired areas, which increases current density.

The second embodiment of the micro light-emitting device 201 may be made by a method similar to the method for making the first embodiment, except that the method for making the second embodiment further includes the following steps.

The current-spreading layer 105 is patterned to form the through holes 105a. The metal reflective layer 106 is then formed on the current-spreading layer 105 so as to improve the reflectance of light. With the design of the metal reflective layer 106, the periphery area 104A, the ohmic contact region 104B, and the exposed part 104C of the top portion, current flow may be easier to be controlled, and the non-radiative re-combinations may be avoided. It is noted that, in case that a second electrode (e.g. P-type electrode), rather than the metal reflective layer 106, is formed on the current-spreading layer 105, a specialized design for the second electrode, e.g., size, position, and structure pattern, may alter the current spreading effect. However, because the second electrode may be made of metal that has a lower reflectivity and may have to be subjected to an annealing process, light absorption of the micro light-emitting device 201 may be increased, thereby decreasing luminous efficiency.

Therefore, in the second embodiment, the current-spreading layer 105 may form an ohmic contact with the second type semiconductor layer 104 (which may include P-type gallium nitride, or P-type aluminum gallium indium phosphide), the conductivity of the periphery area 104A is reduced, and the current-spreading layer 105 is patterned to form the exposed part 104C of the non-ohmic contact region. Through the aforesaid configurations, current flow may be controlled. Moreover, when operating under a low current density, the current in the micro lighting-emitting device 201 may not flow through the side of the second mesa portion, and thus the non-radiative re-combinations may be avoided.

Referring again to FIG. 4, the second type semiconductor layer 104 that is in contact with the current-spreading layer 105 forms the ohmic contact region 104B. The periphery area 104A and the exposed part 104C of the top portion of the epitaxial unit form the non-ohmic contact region. As shown in FIG. 4, the current flows through the current-spreading layer 105 to the active layer 103 so as to produce effective radiative re-combinations. The currents may not flow through the periphery area 104A even though the periphery area 104A is in contact with the current-spreading layer 105. Therefore, the non-radiative re-combinations may be avoided.

In the second embodiment, a cross-sectional area of the current-spreading layer 105 that is in contact with the second type semiconductor layer 104 is 10% to 95% of a total cross-sectional area of the current-spreading layer 105 and the through holes 105a. In other words, the through holes 105a have a cross-sectional area ranging from 5% to 90% of the total area of the current-spreading layer 105 and the through holes 105a.

It is noted that, in certain embodiments, an annealing step may be conducted after ion implantation and before forming the current-spreading layer 105. The annealing step is conducted at a temperature ranging from 700° C. to 1000° C. By conducting the annealing step, diffusion of the implanted ions in the periphery area 104A may be improved so as to facilitate reduction in conductivity.

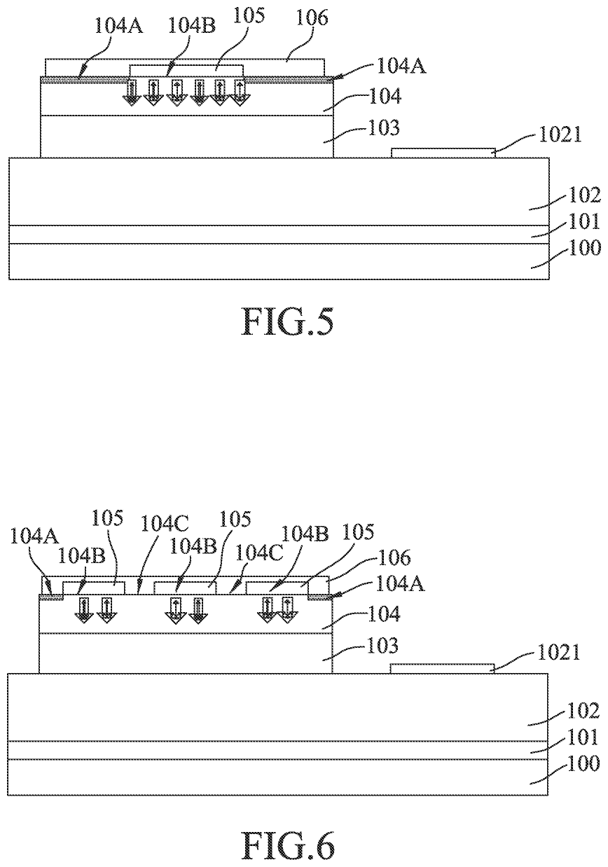

Referring to FIG. 5, a third embodiment of the micro light-emitting device 201 of the disclosure is similar to the first embodiment, except that the current-spreading layer 105 is only disposed on the ohmic contact region 104B and not on the periphery area 104A, and the periphery area 104A and the current-spreading layer 105 are covered by the metal reflective layer 106. Therefore, the reflectivity of the metal reflective layer 106 is increased correspondingly.

In this embodiment, a ratio of the area of the surface of the periphery area 104A to the area of the surface of the top portion of the epitaxial unit is 50%.

The method for making the third embodiment of the micro light-emitting device 201 is similar to the method for making the first embodiment.

Referring to FIG. 6, a fourth embodiment of the micro light-emitting device 201 of the disclosure is similar to the second embodiment, except that the current-spreading layer 105 is formed with a plurality of trenches, and is not disposed on the periphery area 104A.

The current-spreading layer 105 is divided by the trenches into a plurality of current-spreading portions that are spaced apart by the trenches.

It should be noted that, in FIG. 4, the current-spreading layer 105 formed with the through holes 105a is a continuous layer; while in FIG. 6, the current-spreading layer 105 formed with the trenches are divided into the current-spreading portions that are separated from one another.

In this embodiment, a distance between two adjacent ones of the current-spreading portions ranges from 1 μm to 10 μm, thereby providing a desired current spreading effect.

The method for making the fourth embodiment of the micro light-emitting device 201 is similar to the method for making the second embodiment.

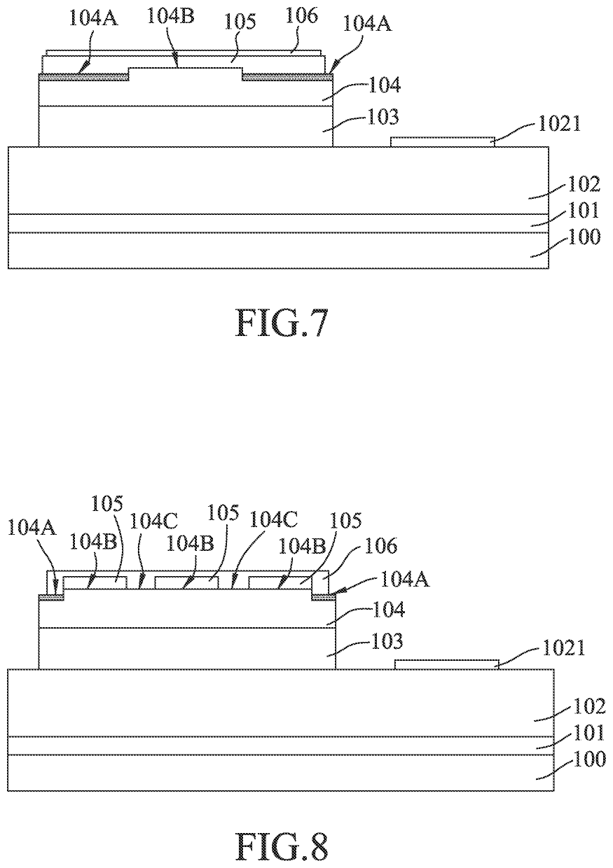

Referring to FIG. 7, a fifth embodiment of the micro light-emitting device 201 of the disclosure is similar to the first embodiment, except that, instead of ion implantation, the periphery area 104A in the fifth embodiment is formed by a structure destructing process so as to have reduced conductivity compared with the remainder of the top portion.

In this embodiment, the structure destructing process is a plasma bombarding process. More specifically, the plasma bombarding process may use a high power plasma. The plasma bombarding process may use a plasma source, e.g., argon, oxygen, carbon tetrachloride, or combinations thereof. A power used to produce the plasma may be no less than 1000 W.

Through the plasma bombarding process, a lattice structure (e.g., carbon-doped gallium phosphide) of the periphery area 104A of the top portion (that is the part of the second type semiconductor layer 104) is destructed so as to form the non-ohmic contact region.

In this embodiment, after the plasma bombarding process, the periphery area 104A has a loose structure. A conductivity of the loose structure is reduced so that the periphery area 104A may form non-ohmic contact regardless of a material of a neighboring layer which is in contact with the periphery area 104A. In other words, the current may be prevented from flowing toward the periphery area 104A even though the periphery area 104A is in contact with the current-spreading layer 105 or other layers (e.g., the metal reflective layer 106). Therefore, non-radiative re-combinations may be avoided so as to improve the luminous efficiency under a low current density.

The method for forming the fifth embodiment of the micro light-emitting device 201 is similar to the first embodiment except that ion implantation is replaced by the structure destructing process, e.g., the plasma bombarding process. After the structure destructing process, the current-spreading layer 105 is formed on the epitaxial unit to cover the periphery area 104A and the ohmic contact portion 104B, followed by forming the metal reflective layer 106 on the current-spreading layer 105.

Similar to the aforesaid embodiments, the micro light-emitting device 201 of the fifth embodiment may be a flip-chip structure, a wire bonding structure, or a vertical LED structure.

Referring to FIG. 8, a sixth embodiment of the micro light-emitting device 201 of the disclosure is similar to the second embodiment, except that, instead of ion implantation, the periphery area 104A is formed by the structure destructing process. Moreover, the current-spreading layer 105 is only formed on the ohmic contact region 104B without being formed on the periphery area 104A.

In this embodiment, the periphery area 104A has a loose structure, and has a conductivity lower than that of the exposed part 104C of the top portion of the epitaxial unit. Furthermore, the non-ohmic contact region further includes the exposed part 104C of the top portion of the epitaxial unit in addition to the periphery area 104A. The periphery area 104A and the exposed part 104C of the top portion of the epitaxial unit may control current flow.

In this embodiment, the metal reflective layer 106 may be further formed on the current-spreading layer 105 so as to enhance the luminous efficiency of the micro light-emitting device 201.

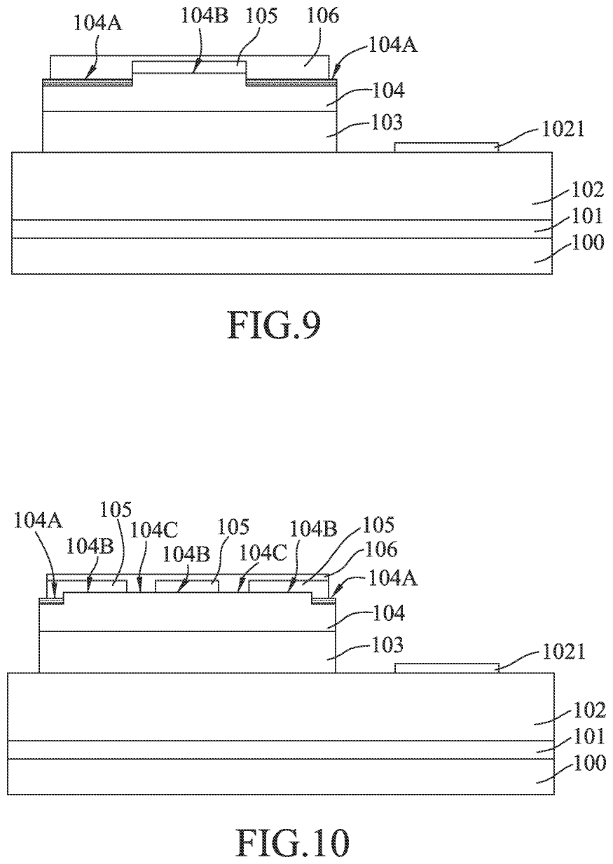

Referring to FIG. 9, a seventh embodiment of the micro light-emitting device 201 of the disclosure is similar to the fifth embodiment, except that, in the seventh embodiment, the current-spreading layer 105 is only formed on the ohmic contact portion 104B without being formed on the periphery area 104A.

In certain embodiments, a surface of the periphery area 104A is lower than a surface of the ohmic contact portion 104.

In certain embodiments, a distance between the surface of the periphery area 104A and the surface of the ohmic contact portion 104B may range from 400 Å to 1000 Å.

In this embodiment, the periphery area 104A may be made of carbon-doped gallium phosphide, and may have a thickness about 400 Å. The distance between the surface of the periphery area 104A and the surface of the ohmic contact portion 104B which is greater than 400 Å may have a better non-ohmic contact, and current conduction may not occur in the periphery area 104A. However, the greater the distance between the surface of the periphery area 104A and the surface of the ohmic contact portion 104B, the higher the cost and processing time are. Therefore, in certain embodiment, the distance is controlled to range from 400 Å to 1000 Å.

In certain embodiments, the periphery area 104A having the surface lower than the surface of the ohmic contact portion 104B may be made by an inductively coupled plasma (ICP) etching process. The ICP etching process may also reduce the conductivity of the periphery area 104A and form a loose structure the same as that of the fifth embodiment.

A gas used in the ICP etching process may be chlorine, boron tri-chloride, argon, sulfur hexafluoride, hydrogen bromide, oxygen, or combinations thereof.

After the ICP etching process, the periphery area 104A may have a roughness greater than a roughness before being subjected to the ICP etching process. The roughness of the periphery area 104A after the ICP etching process may be greater than 5 nm. The ohmic contact region 104B that is not subjected to the ICP etching process may have a roughness ranging from 2 nm to 5 nm (e.g., 2 nm).

Referring to FIG. 10, an eighth embodiment of the micro light-emitting device 201 of the disclosure is similar to the fourth embodiment shown in FIG. 6, except that, instead of ion implantation, the periphery area 104A in the eighth embodiment is formed by a structure destructing process so as to have reduced conductivity compared with the remainder of the top portion. The surface of the periphery area 104A is lower than the surface of the ohmic contact region 104B. The structure destructing process used in this embodiment may be the aforesaid structure destructing process. Moreover, in this embodiment, the current-spreading layer 105 also covers the periphery area 104A.

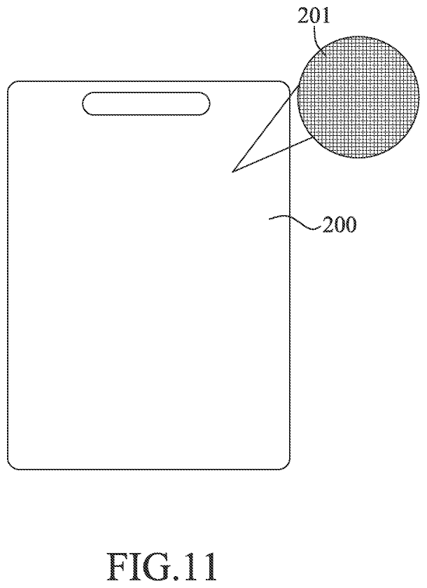

FIG. 11 illustrates an embodiment of a display screen 200 according to the present disclosure. The display screen 200 includes a plurality of the micro light-emitting devices 201 of the aforesaid embodiments of this disclosure. The micro light-emitting devices 201 are arranged in a matrix, and a part of the micro light-emitting devices 201 is shown in an enlarged view in FIG. 11.

In this embodiment, the display screen 200 may be a display used in any device, e.g., a smart phone, laptop, smart wearable device, etc.

By including the micro light-emitting device 201, the display screen 200 is conferred with the advantages provided by the micro light-emitting device 201.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A micro light-emitting device, comprising:
an epitaxial unit having a top portion that includes an ohmic contact region and a non-ohmic contact region, said top portion having a periphery area which forms at least a part of said non-ohmic contact region, said periphery area having a reduced conductivity compared with the remainder of said top portion; and
a current-spreading layer disposed on said ohmic contact region.

2. The micro light-emitting device according to claim 1, wherein said periphery area is formed by ion implantation so that said periphery area is an ion implanting area having high impedance.

3. The micro light-emitting device according to claim 2, wherein said periphery area includes implanted ions, said implanted ions including at least one of argon ions and nitrogen ions.

4. The micro light-emitting device according to claim 2, wherein said periphery area has a roughness ranging from 3 nm to 30 nm.

5. The micro light-emitting device according to claim 1, wherein said periphery area has a roughness that is greater than a roughness of said ohmic contact region.

6. The micro light-emitting device according to claim 1, wherein said current-spreading layer is formed with a plurality of through holes.

7. The micro light-emitting device according to claim 1, wherein said current-spreading layer includes a plurality of current-spreading portions that are spaced apart from each other.

8. The micro light-emitting device according to claim 1, further comprising a metal reflective layer disposed on said non-ohmic contact portion and said current-spreading layer.

9. The micro light-emitting device according to claim 8, wherein said metal reflective layer has a thickness no less than 300 Å.

10. The micro light-emitting device according to claim 1, wherein said current-spreading layer has a thickness ranging from 10 Å to 3000 Å.

11. The micro light-emitting device according to claim 1, wherein said current-spreading layer is further disposed on said periphery area.

12. The micro light-emitting device according to claim 1, wherein said periphery area is formed by a structure destructing process.

13. The micro light-emitting device according to claim 12, wherein said periphery area has a surface lower than a surface of said ohmic contact portion.

14. The micro light-emitting device according to claim 13, wherein a distance between said surface of said periphery area and said surface of said ohmic contact portion ranges from 400 Å to 1000 Å.

15. The micro light-emitting device according to claim 12, wherein said periphery area has a roughness no less than 5 nm.

16. The micro light-emitting device according to claim 12, wherein said structure destructing process includes one of a plasma bombarding process, an inductively coupled plasma etching process, and a combination thereof.

17. A method for making a micro light-emitting device, comprising the steps of:
forming an epitaxial unit that includes a first type semiconductor layer, an active layer and a second type semiconductor layer, the epitaxial unit having a top portion which has a periphery area;
subjecting the periphery area of the epitaxial unit to surface treatment so that the periphery area has a reduced conductivity compared with a remainder of the top portion so as to form a non-ohmic contact region; and
forming a current-spreading layer on the epitaxial unit, at least a part of the top portion of the epitaxial unit in contact with the current-spreading layer forming an ohmic contact region.

18. The method according to claim 17, wherein the step of subjecting the periphery area to surface treatment includes:
forming on the epitaxial unit, a silicon dioxide layer;
forming on the silicon dioxide layer, a photoresist layer such that the periphery area is non-overlapping with the photoresist layer; and
conducting ion implantation using the photoresist layer as a mask.

19. The method according to claim 18, wherein the ion implantation uses at least one of argon ions and nitrogen ions.

20. The method according to claim 17, wherein a ratio of an area of a surface of the periphery area to an area of a surface of the top portion of the epitaxial unit ranges from 30% to 80%.

21. A display screen, comprising a micro light-emitting device as claimed in claim 1.
